(19) United States
(12) Patent Application Publication
(10) Pub. No.: US 2002/0076130 A1
(43) Pub. Date: Jun. 20, 2002

(54) Integrated optical device

(76) Inventor: Gregory Pandraud, Kidlington (GB)

Correspondence Address: Daniel Y.J. Kim, FLESHNER & KIM, LLP, P.O. Box 221200, Chantilly, VA, 20153-1200, US

(21) Appl. No.: 09/736,192

(22) Filed: Dec. 15, 2000

(30) Foreign Application Priority Data
Dec. 14, 2000 (GB) GB0030442.8

(51) Int. Cl. G02B 6/12; H01L 21/00

(52) U.S. Cl. 385/14; 438/69; 438/459

(57) ABSTRACT

A method of fabricating an integrated optical device comprising an optically conductive layer (6) separated from a substrate (2) by an optical confinement layer (3) comprising forming the device by bonding two separate parts (1, 4) together at an interface (4A) therebetween and forming a first feature (5) at the interface (4A) by processing at least one (4) of the two parts before the two parts (1,4) are bonded together. The method is particularly applicable to fabricating devices in silicon-on-insulator with the feature (5) located away from the outer surface thereof.

### BACKGROUND OF THE INVENTION

1. Field of the Invention

This invention relates to a method of fabricating integrated optical devices and, in particular, devices comprising a layer of silicon separated from a substrate by an insulating layer and to devices fabricated by the method.

2. Background of the Related Art

It is known to fabricate a silicon-on-insulator (SOI) wafer for use in microelectronics or for integrated optics by forming an oxide layer within a silicon substrate and then forming a silicon layer over the oxide layer, e.g. by epitaxial growth. Features of the electronic and/or optical circuit are then fabricated in the upper silicon layer.

With the increasing use of SOI wafers for integrated optics, and the increased complexity of such devices, it would be desirable to provide other ways of fabricating the devices.

The above references are incorporated by reference herein where appropriate for appropriate teachings of additional or alternative details, features and/or technical background.

### SUMMARY OF THE INVENTION

An object of the invention is to solve at least the above problems and/or disadvantages and to provide at least the advantages described hereinafter.

According to a first aspect of the invention, there is provided a method of fabricating an integrated optical device comprising an optically conductive layer separated from a substrate by an optical confinement layer including the steps of forming the device by bonding two separate parts together at an interface therebetween, and forming a first feature at the interface by processing at least one of the two parts before the two parts are bonded together.

According to another aspect of the invention, there is provided an integrated optical device on a silicon-on-insulator chip fabricated by such a method.

According to a further aspect of the invention, there is provided an integrated optical device comprising an optically conductive layer separated from substrate by an optical confinement layer, the device having been formed from two parts bonded together at an interface, a first feature being provided at the interface by processing at least one of the two parts before the two parts are bonded together.

To achieve the above objects of the present invention in a whole or in parts there is provided a method of fabricating an integrated optical device that includes forming an optically conductive layer, forming an optical confinement layer separating the optically conductive layer from a substrate, forming the device by bonding two separate parts together at an interface therebetween, and forming a first feature at the interface by processing at least one of the two parts before the two parts are bonded together.

To further achieve the above objects of the present invention in a whole or in parts there is provided an integrated optical device that includes an optically conductive layer, a substrate, an optical confinement layer, wherein the optically conductive layer is separated from the substrate by the optical confinement layer, and two parts bonded together at an interface, wherein a first feature is provided at the interface by processing at least one of the two parts before the two parts are bonded together.

Additional advantages, objects, and features of the invention will be set forth in part in the description which follows and in part will become apparent to those having ordinary skill in the art upon examination of the following or may be learned from practice of the invention. The objects and advantages of the invention may be realized and attained as particularly pointed out in the appended claims.

### BRIEF DESCRIPTION OF THE DRAWINGS

The invention will be described in detail with reference to the following drawings in which like reference numerals refer to like elements wherein:

FIGS. 1A-1C are schematic diagrams illustrating steps of one embodiment of a method according to the present invention;

FIGS. 2A-2C, 3A-3C and 4A-4C are schematic drawings illustrating further embodiments of methods according to the present invention; and

FIGS. 5 and 6 are schematic side views of two types of device that may be formed by such methods.

### DETAILED DESCRIPTION OF PREFERRED EMBODIMENTS

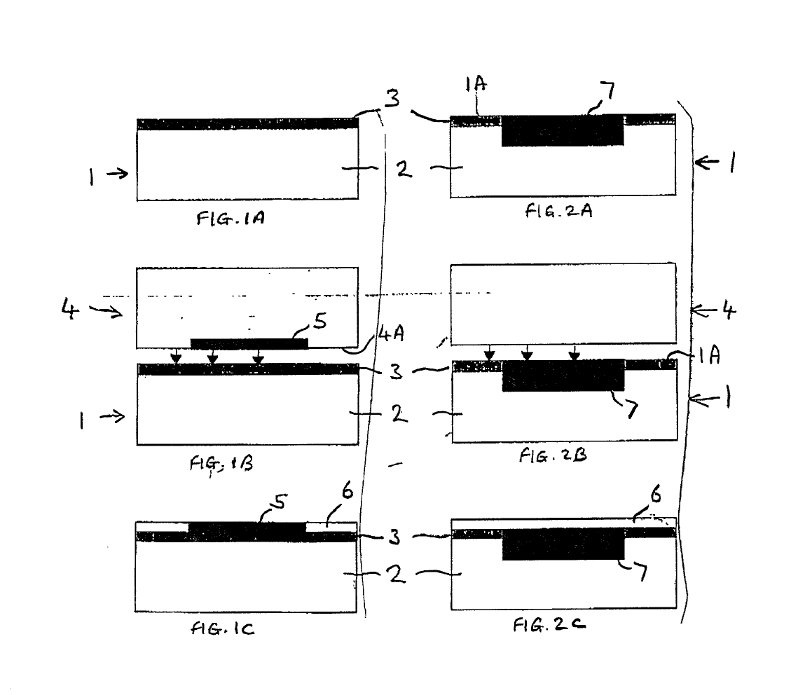

FIG. 1A shows a first wafer 1 comprising a substrate 2, e.g. of silicon, with a layer 3 of oxide, e.g. silicon dioxide, on the surface thereof. A native oxide layer forms on silicon when exposed to air or any other oxygen containing environment and the thickness of this may be increased, e.g. to around 0.4-0.5 microns, by thermal oxidation.

FIG. 1B shows a second wafer 4 formed of silicon. The second wafer 4 has been processed to form a feature on one face 4A thereof as indicated by the shaded region 5. The face 4A is then bonded to the oxide layer 3 of the first wafer 1 as indicated in the Figure.

A preferred bonding technique is known as direct wafer bonding (DWB). Direct wafer bonding generally involves preparation of the surfaces to be bonded to make them as smooth as possible and pressing the two surfaces together. Some form of thermal cycling may also be used to increase the bond strength. Once such process comprises the steps of:

(a) immersing the two wafers 1, 4 in a bath of fluid so as to form OH bonds between the two wafers,

(b) applying pressure to force the two wafers 1, 4 together, and

(c) applying heat to draw H₂O away from the interface between the two wafers so the two wafers are held together by inter-atomic forces, e.g. van der Waals' forces.

Such bonding techniques are well known so will not be described further. Such techniques are capable of forming a very strong bond between two parts such that the interface is no longer detectable and the two parts have, in effect, become one. Other bonding techniques providing a similar result may also be used.

After the two wafers have been bonded together, the silicon layer 6 formed by the second wafer 4 may be further processed, e.g. to reduce its thickness, form further features therein and/or polish its surface. FIG. 1C illustrates a case in which the thickness of the silicon layer 6 has been reduced until the feature 5 is exposed on the outer surface of the layer 6.

The device illustrated in FIG. 1C could, in some cases, be fabricated in the conventional manner, i.e. by processing a silicon-on-insulator chip from the outer surface of the silicon layer but, as will be explained further below, the method described above enables features or devices to be formed which would be impossible, or very difficult, to form by conventional methods and/or which can be formed more easily or with greater accuracy than is possible by conventional methods. For instance, it will be appreciated that if the silicon layer 6 is not reduced in thickness to the extent shown in FIG. 1C, the feature 5 will be buried in the silicon layer 6, i.e. beneath the surface thereof. Such buried features are difficult to fabricate by conventional methods.

The feature 5 may take many forms. In one form, it may comprise a hole or recess which, in the final product contains a fluid, either a gas or liquid, for example air. In another case, the feature 5 may be a doped region. In a further case, it may comprise some other material e.g. a polymer or different semi-conductor material, or any combination of the above.

The feature 5 may also take many shapes (and need not be a simple rectangular shape as shown) depending on the nature of the component to be formed thereby.

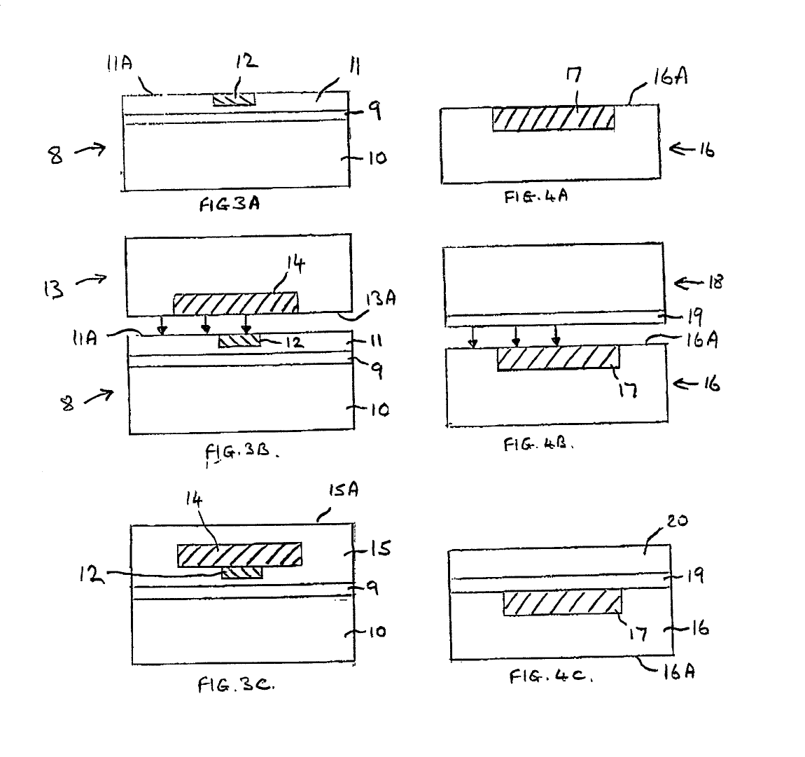

FIGS. 2A-2C illustrate the steps of a method in which the first wafer 1 is processed to form a feature on a surface 1A thereof as indicated by the shaded region 7 in FIG. 2A. A silicon wafer 4 is then bonded to the surface 1A as illustrated in FIG. 2B. The thickness of the silicon layer 6 formed by the wafer 4 may then be reduced, as shown in FIG. 2C. Thus, in this case, a feature is pre-formed in the first wafer 3, which carries the oxide layer 3, before the two wafers are bonded together.

The feature 5 may be formed in just the oxide layer 3 and/or may be formed in the substrate 2 beneath the oxide layer 3 as shown in FIG. 2.

Features may also be pre-formed in both of the two wafers 1, 4 prior to the wafers being bonded together. In some cases, the features in the respective wafers may be designed to be aligned with each other but in other cases this may not be so and they may be independent of each other.

Features 1 and 2 illustrate a method in which the interface between the two parts being bonded together is between the oxide layer 3 and the silicon layer 6. However, the interface may be at other positions within the device.

FIGS. 3A to 3C illustrate a method in which the interface is within the silicon layer. An SOI wafer 8 (which may be fabricated by forming an oxide layer 9 on the substrate 10 and then growing an epitaxial layer of silicon 11 on the oxide layer 9 or by forming an oxide layer 9 on the substrate 10, bonding a silicon wafer to the oxide layer and reducing this silicon layer 11 to the required thickness) is processed to form a feature 12 in the surface 11A of the silicon layer 11 as shown in FIG. 3A.

A second silicon wafer 13 is then bonded to the surface 11A of the silicon layer 11 of the first wafer. The second silicon wafer 13 may also be processed to form a feature 14 in the surface 13A thereof prior to the surfaces 11A and 13A being bonded together.

Once the two wafers have been bonded together, the thickness of the silicon layer 15 formed by the combination of the silicon layer 11 and wafer 13 is reduced to the required level. The features 12 and 14 are thus formed within the silicon layer 15 as shown in FIG. 3C.

It will be appreciated that a feature need not be formed in both wafers prior to bonding but in only one of the wafers, either layer 11 or wafer 13. The feature(s) may also, if desired, extend to the oxide layer 9 and/or to the surface 15A of the silicon layer 15.

FIGS. 4A to 4C illustrate a method in which the interface is between the substrate and the oxide layer. A silicon wafer 16 is processed to form a feature 17 in a surface 16A thereof as shown in FIG. 4A. A second silicon wafer 18 with an oxide layer 19 formed thereon is then bonded to the surface 16A of the first wafer as shown in FIG. 4B. Once the two wafers have been bonded together, the thickness of the silicon layer 20 formed by the second wafer 18 is reduced to the required level. The feature 17 is thus formed in the substrate 16 beneath the oxide layer 19.

The feature 17 may, if desired, extend from the oxide layer 19 to the underside 16A of the substrate.

A further feature may, if desired, be formed in the surface of the second wafer 18 bonded to the first wafer 16 prior to bonding the wafers together.

Other features may be formed in the silicon layer 20 before and/or after the two wafers are bonded together.

In all the cases described above, the feature(s) formed in the wafer(s) prior to bonding may take a variety of forms. As mentioned, they may comprise one or more holes or recesses etched into the surface which are filled with air or some other fluid to define one or more components in the silicon layer. They may also comprise doped areas or areas where another material, e.g. polymer or a different semi-conductor material, has been deposited or they may comprise any combination of such elements.

Such holes or recesses may thus be filled with material of a different refractive index than the surrounding material and, each hole or a plurality of holes may be shaped or configured to act as an optical component, e.g. a lens or prism. Alternatively, the holes may define an optical component in the remaining areas of material therebetween or the holes and the remaining material may together form an optical component.

A significant advantage of the methods described is that different parts of an optical device may be fabricated independently of each other, i.e. the processing steps used to fabricate features in one wafer can be carried out entirely independently of processing steps used to fabricate features in the other wafer before the two wafers are bonded together. This increases the choice of processing techniques which may be used in each case and, in particular, enables each of the features to be fabricated to a degree of accuracy greater than would normally be possible if the features were all fabricated on a single wafer.

As indicated above, the features pre-formed on the wafers prior to bonding the wafers together may be buried within the final device. However, they may also be formed so as to extend to an outer surface of the optically conductive layer and/or of the substrate or the thickness of the optically conductive layer and/or the substrate may be reduced until the feature is accessible from an outer surface thereof. Alternatively, or additionally, the optically conductive layer and/or the substrate may be processed after the wafers have been bonded together to provide one or more connections between an outer surface of the device and one or more features buried therein. Such a connection may comprise an optical and/or on an electrical connection and may take a variety of forms. It may, for instance, comprise one or more holes or recesses (filed with air or some other fluid) etched in the device, doped areas or areas filled or partially filled with other material or any combination thereof.

The methods described above can be used to form a wide variety of devices which will not be discussed here although some basic devices or elements which may be formed in this way will be described below.

The feature formed at the interface between the two bonded wafers may, for example comprise a waveguide, e.g. extending in a direction substantially parallel to the plane of the interface.

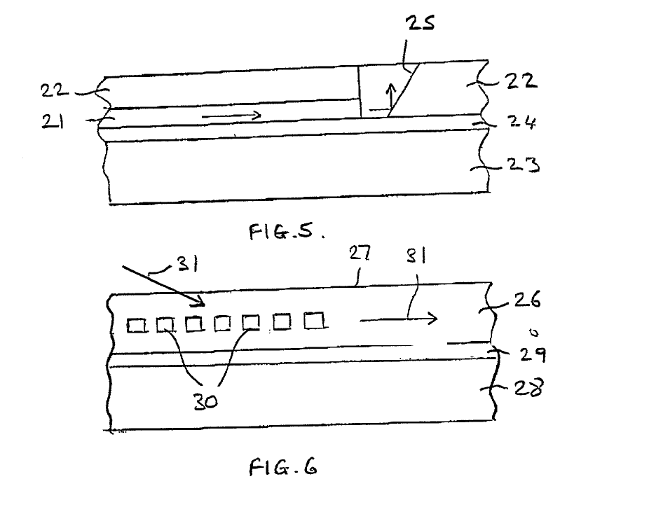

FIG. 5 shows a schematic side view of a waveguide 21 formed in a silicon layer 22 separated from a substrate 23 by an oxide layer 24.

The waveguide 21 may comprise an elongate region having a refractive index differing from that of the surrounding material, e.g. a doped region or a region of different material to the surrounding material, or an elongate region one or more sides of which are defined by elongate holes or channels within the material.

A hole or recess may also be formed in the silicon layer 22 with a reflective facet 25 positioned to re-direct light received from the waveguide 21, in this case out of the chip or to a component (not shown) on the surface of the chip. The hole or recess may also be elongate, e.g. in the form of a trench, and arranged to re-direct light received from a plurality of waveguides.

In another arrangement, the features formed at the interface between the two bonded wafers may have a periodic structure so as to act as a grating for receiving light incident upon the device or directing light out of the device.

FIG. 6 shows a schematic side view of a waveguide 26 formed in a silicon layer 27 separated from a substrate 28 by an oxide layer 29. Part of the waveguide 26 is formed with a periodic structure 30 as shown. The periodic structure 30 may take many forms which provide a periodicity in the refractive index of the waveguide along its length. It may, for instance, comprise alternating regions of silicon and holes (filled with air or other material) or alternating regions having different dopant levels or any other periodic structure known in the field which can be fabricated by the method described above. As indicated by arrows 31 in FIG. 6, light incident upon the chip or from a device (not shown) mounted on the chip, received by the grating formed by the periodic structure 30 is received by the waveguide 26 and transmitted along the waveguide.

It will be appreciated that both of the devices shown in FIGS. 5 and 6 can be operated in either direction, i.e. for receiving light into a waveguide in the device or transmitting light from the waveguide in the device.

As described above, the fabrication methods described herein are particularly suitable for fabricating optical devices in silicon-on-insulator (SOI) chips. Such chips comprise an optically conductive silicon layer separated from a substrate, which is also usually of silicon, by an insulating layer, such as an oxide, typically silicon dioxide.

The term ‘insulating layer’ is derived from the initial use of SOI chips for the fabrication of electronic integrated circuits. When such chips are used for fabrication of optical integrated circuits, this layer acts as an optical confinement layer, i.e. it serves to confine optical modes within the optically conductive silicon layer due to it either not being optically conductive or having a higher refractive index than the optically conductive silicon layer.

Whilst the use of silicon as the optically conductive layer and the use of silicon dioxide as the optical confinement layer is preferred, it will be appreciated that the methods described above may also be suitable for fabricating integrated optical circuits in which the optically conductive layer and/or the optical confinement layer are formed of other materials.

The methods described above may also be extended to bond more than two parts together. Two or more parts may, for instance, be bonded side-by-side to the same wafer on three or more parts may be bonded together in a stack. One or more further features may thus be formed at the interface between these parts by processing at least one of the respective parts prior to bonding them together.

The foregoing embodiments and advantages are merely exemplary and are not to be construed as limiting the present invention. The present teaching can be readily applied to other types of apparatuses. The description of the present invention is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures.

What is claimed is:

1. A method of fabricating an integrated optical device, comprising:
forming an optically conductive layer;
forming an optical confinement layer separating the optically conductive layer from a substrate;
forming the device by bonding two separate parts together at an interface therebetween; and
forming a first feature at the interface by processing at least one of the two parts before the two parts are bonded together.

2. The method of claim 1, wherein the interface is between the optically conductive layer and the optical confinement layer.

3. The method of claim 1, wherein the interface is within the optically conductive layer.

4. The method of claim 1, wherein the interface is between the substrate and the optical confinement layer.

5. The method of claim 1, wherein the first feature is formed in only one of the parts.

6. The method of claim 1, wherein the first feature comprises:
a first element in one of the parts; and
a second element in the other of the parts, wherein the two parts are aligned so the first and second elements are aligned with each other.

7. The method of claim 1, wherein the first feature comprises a hole filled with fluid.

8. The method of claim 7, wherein the fluid is air.

9. The method of claim 1, wherein the optically conductive layer and the substrate are formed of a first material or of a first material and a second material respectively, and the first feature comprises a region of a third material which differs from the first and/or the second material.

10. The method of claim 9, wherein the third material differs from the first and/or second materials by virtue of dopant with the said region.

11. The method of claim 9, wherein the first and/or second materials are semiconductors and the said region comprises a different semiconductor material.

12. The method of claim 1, wherein the optically conductive layer is formed of silicon.

13. The method of claim 1, wherein the optical confinement layer comprises an oxide.

14. The method of claim 13, wherein the oxide comprises silicon dioxide.

15. The method of claim 1, wherein the two parts are bonded together by a direct bonding technique.

16. The method of claim 15, wherein the direct bonding technique comprises:
immersing the two parts in a bath of fluid so as to form OH bonds between the two parts;
applying pressure to force the two parts together; and
applying heat to drive H₂O away from the interface whereby the two parts are held together by van der Waals' forces.

17. The method of claim 1, comprising the further step of reducing the thickness of one or both of the two parts after the two parts have been bonded together.

18. The method of claim 1, comprising the further step of polishing an outer surface of the optically conductive layer after the two parts have been bonded together.

19. The method of claim 1, comprising the further step of fabricating a second feature, before and/or after the two parts are bonded together, in the first and/or second part to provide a connection between the first feature and an outer surface of the device.

20. The method of claim 1, wherein one or more further parts are bonded to either the first and/or second part at a further interface therebetween, a further feature being formed at the further interface by processing at least one of the respective parts prior to bonding them together.

21. An integrated optical device, comprising:
an optically conductive layer;
a substrate;
an optical confinement layer, wherein the optically conductive layer is separated from the substrate by the optical confinement layer; and
two parts bonded together at an interface, wherein a first feature is provided at the interface by processing at least one of the two parts before the two parts are bonded together.

22. The device of claim 21, wherein the first feature is located at a boundary between the layer of optically conductive material and the layer of optical confinement material.

23. The device of claim 21, wherein the first feature is within the layer of optically conductive material.

24. The device of claim 21, wherein the first feature is located at a boundary between the substrate and the layer of optical confinement material.

25. The device of claim 21, wherein the first feature comprises a hole filled with fluid.

26. The device of claim 25, wherein the fluid is air.

27. The device of claim 25, further comprising an optical waveguide, wherein a side of the hole provides a reflective face positioned to re-direct light to or from the waveguide.

28. The device of claim 21, wherein the first feature has a periodic structure so as to act as a grating for receiving light incident upon the device or directing light out of the device.

29. The device of claim 21, wherein the optically conductive layer and the substrate comprise a first material or first and second materials respectively, and the first feature comprises a region of a third material which differs from the first and/or the second material.

30. The device of claim 29, wherein the third material differs from the first and/or second material by virtue of a dopant within the said region.

31. The device of claim 29, wherein the first and/or second materials are semiconductors and the said region comprises a different semi-conductor material.

32. The device of claim 21, wherein the optically conductive material is silicon.

33. The device of claim 21, wherein the optical confinement material comprises an oxide.

34. The device of claim 33, wherein the oxide is silicon dioxide.

35. The device of claim 21, wherein the feature comprises an optical waveguide.

36. The device of claim 21, further comprising a second feature which provides a connection between the first feature and an outer surface of the device.

37. The device of claim 36, wherein the second feature comprises an electrical connection.

38. The device of claim 36, wherein the second feature comprises an optical connection.

39. An integrated optical device on a silicon-on-insulator chip fabricated by the method of claim 1.
